(19) United States
(12) Patent Application Publication
(10) Pub. No.: US 2009/0029490 A1
(43) Pub. Date: Jan. 29, 2009

(54) Method of fabricating an electronic device

(76) Inventors: Frank A. Baiocchi, Allentown, PA (US); James Thomas Cargo, Bethlehem, PA (US); John Michael DeLucca, Wayne, PA (US); Edward B. Harris, Fogelsville, PA (US)

Correspondence Address: Bruce S. Schneider, 1153 Long Hill Road, Stirling, NJ, 07980-1007, US

(21) Appl. No.: 12/220,169

(22) Filed: Jul. 22, 2008

Related U.S. Application Data
(60) Provisional application No. 60/962,129, filed on Jul. 26, 2007.

(51) Int. Cl. H01L 21/66

(52) U.S. Cl. 438/14; 257/E21.529

(57) ABSTRACT

It has been found that for silicon integrated circuits having capacitor structures or other p-n junctions structure at a technology node of 32 nm or smaller, photovoltaic induced corrosion of copper in the metallization stack is a significant issue. Thus processing conditions or device configurations are employed that preclude such corrosion. In one embodiment photovoltaic induced corrosion is monitored to prevent completion of devices with corrosion defects.

### CROSS REFERENCE TO RELATED APPLICATIONS

This application claims priority to provisional application 60/962,129 filed Jul. 26, 2007 which is hereby incorporated in its entirety by reference.

### TECHNICAL FIELD

This invention relates to the fabrication of electronic devices such as silicon based integrated circuits and in particular to the fabrication of electronic devices having capacitor elements.

### BACKGROUND OF THE INVENTION

In the fabrication of integrated circuits such as silicon based integrated circuits the device is generally constructed by the formation and patterning of sequential material layers. For example, as shown in FIG. 1, a device is built on a single crystal silicon substrate, 6. The sources, 5, drains, 8, and gates, 7, of transistors together with their associated contacts are formed by conventional implantation, diffusion, layer formation and patterning techniques such as described in VLSI Technology, S. M. Sze, McGraw-Hill, 1988. In one approach, contacts, 3, to the sources and drains are made through a dielectric layer, 4, using materials such as tungsten. Additionally, many applications require a capacitor array as a constituent part of the integrated circuit. These arrays are generally fabricated in the same material layers involved in formation of the transistor source, drain, gate, and associated contacts. Various configurations for capacitors of such arrays are employed. For example, as shown in FIG. 2, an ion implanted n-well, 21, is formed in the bulk single crystal silicon substrate, 6, and functions as the capacitor bottom plate. The capacitor dielectric layer, 22, (generally formed from the same layer as the gate dielectric) is structured between the n-well, 21, and the upper plate, 23, which is formed in the same layer as the gate poly-silicon of the transistor region. The upper plate and the lower plate contacts (24 and 27 respectively) are introduced through dielectric layer, 4, together with the transistor source and drain contacts. Another capacitor configuration is shown in FIG. 3 with components corresponding to those in FIG. 2 including upper plate 23, contacts 24 and 27, capacitor dielectric 22, and dielectric layer 4. In contrast to the configuration of FIG. 2, an isolated p-well, 31, and an n-type deep well, 33 are employed.

After the previously discussed transistor region and capacitor array constituent components are fabricated, subsequent layers are formed and patterned to electrically interconnect such components in the desired electrical circuit configuration. These interconnection layers are typically denominated the metallization stack and for technology nodes of 0.13 μm and smaller are presently produced by a copper single or dual damascene process. (Technology node in the context of this invention refers to the nominal gate channel length dimension.) Such damascene procedures, in one approach, involve deposition of a dielectric layer, 1 (often denominated in the trade dielectric I); dry etching through dielectric, 1, to form regions, 16, patterned for such etching by conventional lithography; wet chemical cleaning to remove etching residue; subsequent sequential deposition by sputtering or chemical vapor deposition of a thin barrier layer (e.g. a tantalum or tantalum nitride region) and a seed layer, (in one approach a copper deposition) for subsequent bulk copper deposition; wet electrochemical deposition of such a copper region into etched regions, 16, and onto dielectric, 1; and removal of the copper region thus formed on dielectric region 1 by chemical-mechanical polishing (CMP). The single or dual damascene process is repeated generally with alternating dielectric and copper regions to form overlying regions of the metallization stack such as, for illustration, dielectric region 2 (dielectric II), copper region 15 (metal II), dielectric, 17 (dielectric III) and copper region, 14 with copper vias, 12 (metal III).

The intricacy of this processing sequence naturally affords numerous possibilities for defects occurring during manufacturing. In fact the literature is replete with unexpected consequences associated with seemingly innocuous fabrication conditions. Such effects are, at times, associated with temperature, pressure, electromagnetic radiation, material composition, electromigration, electrostatic discharge, process chemistry, and other process equipment variations. Additionally, as the device integration becomes more dense, more metal layers have been used with copper regions of greater pattern complexity and of smaller dimension. For example, in integrated circuit devices at the 65 nm technology node copper regions with dimensions of 200 nm thickness by 100 nm width are employed. It is commonly believed that as technology nodes become smaller this trend of greater complexity and finer dimensions will continue at an accelerated rate. The benefits of greater integration consequently are likely to require continued diligence in correcting unexpected, undesirable processing results occurring as technology nodes shrink.

### SUMMARY OF THE INVENTION

It has been found that for the coming generations of integrated circuits, i.e. for integrated circuits of 32 nm and smaller, the processing of devices having a capacitor array, or other structures having a p-n junction, requires the use of an expedient that avoids unacceptable and totally unexpected corrosion of copper regions in the metallization stack. In particular light incident on p-n junction regions in, for example, the capacitor array during processing causes electrochemical corrosion of copper metallization regions that 1) electrically connect to such junction, and 2) are exposed to an electrically conductive liquid phase medium. For example, in the formation of the device shown in FIG. 1 a stage is reached as shown in FIG. 4 for the cleaning of the vias, 41 (corresponding to vias 12 in FIG. 1) after etching through dielectric III, 42, in which a portion of metal II, 46, is also wet exposed to the clean process through the vias, 41. The metal II region, 43, continues in the direction, 45, through vias, 27 in FIGS. 2 or 3, to the p-n junction, 34 in the capacitor array. Light of energy greater than the bandgap of silicon induces the generation of electron-hole pairs and a subsequent charge separation at such junction. This charge separation causes a positive potential to develop on electrically conductive features connected to the p-side of the p-n junction, and a negative potential to develop on conductive features connected to the n-side of the p-n junction. During the wet chemical cleaning of the vias, 41, these photovoltaically generated charges flow to region 46 and drive the electrochemical corrosion of the exposed metal II copper region, 46, through the cleaning medium that functions as an electrolyte that completes the electrochemical cell. At first blush, it seems a remote possibility that this corrosion would be sufficient to be problematic. However, the small dimensions and pattern complexity of devices at technology nodes of 32 nm and smaller makes unacceptable levels of corrosion a reality.

Thus the invention includes the surprising realizations that 1) a light induced electrochemical corrosion is induced during conventional processing, 2) such corrosion is worse than just an unexpected artifact for devices of technology node at least as strict as 32 nm, and 3) an expedient for preventing such electrochemical corrosion should be employed in the fabrication of these integrated circuits. Suitable expedients include, for example, limiting the ambient light present during processing that produces the driving force for an electrochemical cell configuration, depositing a material layer over a p-n junction that is opaque to indirect ambient light of suitable energy, avoiding exposure to electrolytes of copper regions electrically connected to a p-n junction or preventing exposed copper regions connected to a p-n junction from developing a net positive charge relative to surrounding conductive features by connecting the exposed copper to an appropriate charge dissipating circuit feature.

Additionally, it is advantageous during processing to use test structures to monitor induced corrosion. If unacceptable corrosion is seen to occur in the test structure then further processing of defective device wafers in the manufacturing lot is terminated precluding the associated costs of completing fabrication of device wafers that have concealed defects found only after device completion or after field deployment with associated reliability concerns.

### BRIEF DESCRIPTION OF THE DRAWINGS

FIGS. 1 through 4 are illustrative of device configurations relating to the invention; and

FIGS. 5 and 6 are micrographs showing effects associated with the inventive concept.

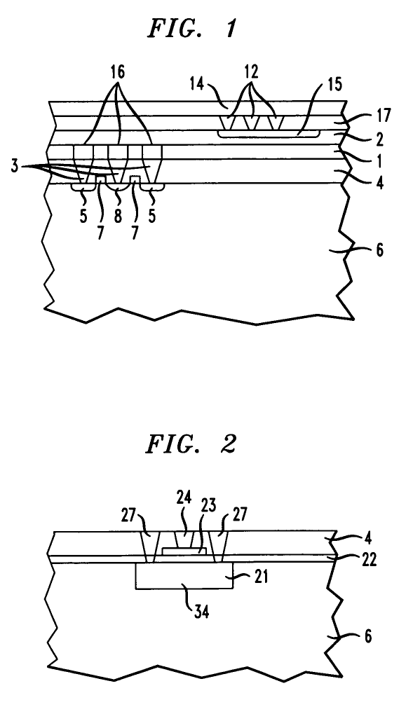

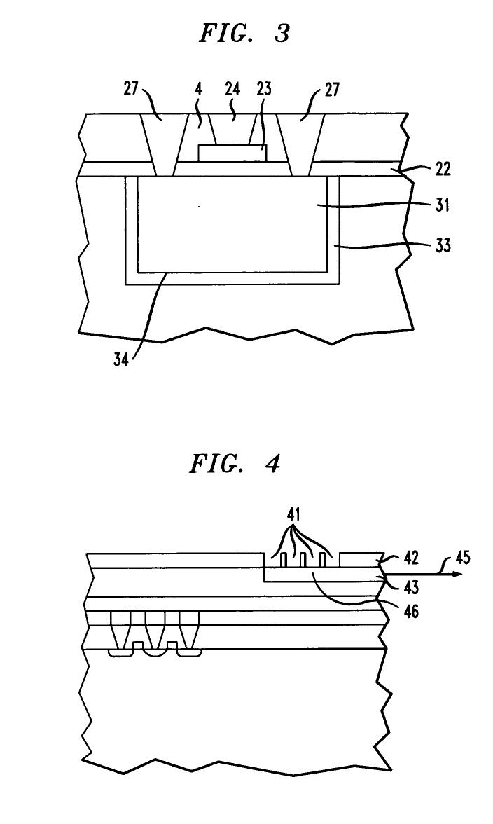

### DETAILED DESCRIPTION

As discussed the invention, in part, involves the realization that light with energy greater than the bandgap of silicon incident on the p-n junction present in integrated circuit elements such as capacitor arrays resistors, diodes, and transistors of integrated circuits provides the driving force for electrochemical corrosion of electrically connected copper metallization regions subjected to electrolytes during processing in the presence of such light. Generally light having a wavelength shorter than 1127 nm is sufficiently energetic to induce separation of charges in silicon based devices if such light is incident at the p-n junction. (Nevertheless, light with wavelengths shorter than 200 nm has insufficiently absorbed cross-section in silicon to induce corrosion.) For example, a substantial portion of ambient light present in integrated circuit fabrication facilities is sufficient to induce generation of electron-hole pairs and subsequent charge separation at p-n junctions.

The dose of sufficiently energetic light incident at, and absorbed by, the p-n junction of for example a capacitor array determines the magnitude of the charge that is separated and thus available for driving the undesirable electrochemical corrosion of copper. As a reasonable estimate of the corrosion process, each charge separated induces corrosion removal of a copper atom present at the interface between an electrolyte, e.g. a cleaning solution for etching residue, and copper regions of the metallization stack with an electrical pathway for such charge. It is undesirable for the corrosive removal of copper either to produce an open or to increase substantially the electrical resistance in the circuitry formed by the metallization stack such that an unacceptable change in device characteristics occurs. The charge required to produce such an open circuit or substantially increased resistance depends on the dimensional cross-section of the copper lines of the metallization stack electrically connected to the lower plate of the capacitor array. (Electrically connected in this context means a path between the lower plate and the corrosion region having an electrical resistance less than 10,000 ohms.) This cross-section is determined by the device technology node. For example, for a 32 nm technology node device, metallization line dimensions of 100 nm long by 250 nm thick by 32 nm wide are being contemplated. For such dimensions light fluxes of 100 lux or greater over typical processing times have the substantial potential to produce unacceptable corrosion for ambient room light incident on a corresponding capacitor array. A controlled sample is employable to determine the level of light producing unacceptable corrosion for a given integrated circuit and given device processing conditions.

Corrosion occurrence even in the presence of suitable energetic light involves such light being incident on the p-n junction of a capacitor array or of another integrated circuit element in the further presence of an electrolyte interfaced with a copper line electrically connected to this junction. The area of p-n junction interface that is sufficient to interact with incident light under the conditions discussed to produce unacceptable corrosion also depends, in a parallel fashion to the above discussion, on the technology node of the integrated circuit being processed. Illustratively, there is a substantial possibility of unacceptable corrosion for technology nodes 32, 22, and 16 nm when a p-n junction (with, for example, area of approximately 3.5, 1.6, and 0.86 μm², respectively) is optically accessible to sufficiently energetic light. (These junction areas are based on typical room lighting intensities and exposure to such light for at least 10 seconds. These illustrations were calculated assuming a metalization thickness of 0.25 μm.) Optically accessible in the context of this invention means that light of wavelength in the range 1127 to 200 nm incident on the device being processed above the p-n junction interface is not substantially attenuated before reaching such interface. More generally, the possibility for unacceptable corrosion is dependent not only on accessible p-n junction area, but also light and intensity and length of exposure. For purposes of estimating the potential level of corrosion it is possible to employ the relation:

Junction Area (in μm²) Inducing Non-Negligible Corrosion=A/[(L)(t)]

where A is a constant combining material and geometric parameters (depending on technology node) and equals 3.5×10⁴, 1.6×10⁴ and 8.6×10³ μm²-Lux-seconds for the 32, 22, and 16 nm technology nodes, respectively; L is the illumination intensity in units of lux; and t is the time in seconds that the junction is exposed to radiation. Thus, higher intensity light and/or exposure of p-n junction area electrically connected to the upper level metallization for longer than 10 seconds shifts the p-n junction area at which unacceptable corrosion is extant to even smaller areas than those given as illustrative for 32, 22, and 16 nm technology nodes. Thus it is possible that one capacitor could have inadequate junction area to induce unacceptable corrosion. Nevertheless if a multiplicity of such small area junctions in, for example, a capacitor array, are electrically connected to a copper region that contacts an electrolyte, the potential for corrosion from this enhanced junction area is present.

Additionally, the junction area in capacitor arrays sufficient to produce the necessary capacitance for device functioning depends on the thickness of the capacitor dielectric and the dielectric constant of this dielectric material. The thinner the dielectric material and the higher the dielectric constant the smaller the junction area needed to produce this necessary capacitance. Hence for a given necessary capacitance, the level of associated corrosion decreases with thinner dielectric layers and higher dielectric constant materials since the p-n junction area required to produce the desired capacitance correspondingly decreases.

Despite the presence of adequate junction area and adequate incident light dose, copper corrosion still requires a fluid electrolyte contacting copper that is electrically connected to a p-n junction area, such as would be used for a capacitor array, large diodes, or other such integrated circuit elements having p-n junctions. (An electrolyte in the context of this invention is a fluid having a conductivity of at least 18 Mohm-cm.) Generally, fluids such as cleaning solutions for etch residue removal, are typical acidic or basic liquids that are considered electrolytes within the context of this invention. Indeed, deionized water typically used for rinsing has sufficient conductivity to be an electrolyte to allow electrochemical reaction. Although many fluids present during processing are electrolytes, corrosion is nevertheless possible for any fluid that is an electrolyte.

Even if electrolytes are employed during processing, it is possible to prevent an interface with a copper region electrically interconnected to the lower plate of a capacitor in the capacitor array. For example, such interface with the electrolyte is prevented by a region, such as a dielectric region, overlying the copper region. (Overlying in the context of this invention means further removed from the single crystal silicon substrate.) Typically the dielectric layers in the metallization stack, e.g. dielectric 11, are continuous and have a contemplated thickness in the range 150 to 1600 nm for the 32 nm technology node. Thus, typically an overlying dielectric region in the metallization stack is sufficient to prevent interface of an electrolyte with an underlying copper region.

As discussed, the issues associated with unacceptable corrosion become particularly problematic for technology nodes of 32 nm and smaller, including for example 22 nm, 16 nm, and beyond. The added complexity of the metallization stack pattern and the increasingly smaller copper region dimensions make devices at smaller and smaller technology nodes more susceptible to the issues associated with corrosion and require addressing. Thus an aspect of this invention includes the use of an expedient that prevents unacceptable corrosion during integrated circuit fabrication. (In the context of this invention, the term expedient is not used as an equivalent of the term means as used in means plus function methods of claiming inventions. Instead, the term expedient is used to convey any approach, whether explicitly disclosed in this specification or not, used to prevent unacceptable corrosion induced by photovoltaic charge separation in copper regions of the metallization stack during processing.)

As discussed above, the corrosion of copper runners during integrated circuit fabrication requires a) light, b) an electrolyte, and c) an exposed portion of a copper feature that carries a net charge with respect to surrounding features due to connection to a p-n junction of a capacitor structure or other integrated circuit structures containing a p-n junction. Unacceptable corrosion is preventable by properly affecting any one of these three factors. Thus there is a variety of expedients for preventing photovoltaic induced unacceptable corrosion. For example, during the presence of an electrolyte, e.g. etch cleaning solution, light is blocked from being incident on the p-n junction electrically connected to metal susceptible to corrosion. In one approach light is blocked by shrouding the processing apparatus in a material opaque to light of sufficient energy to produce photovoltaic charge separation. In a second approach, (that is combinable with the first approach) a material layer that is substantially opaque to incident light in the wavelength range 1127 nm to 200 nm is employed. A substantially opaque layer attenuates light by a factor of at least 90% and is generally achieved by employing a region having a material of sufficient thickness and extinction coefficient. A controlled sample is easily employed to determine a suitable material composition and an associated region thickness.

In another embodiment, the electrolyte is prevented from contacting the susceptible copper region. For example, the pattern of the metallization stack is designed so that during processing with a fluid electrolyte the copper regions electrically connected to a p-n junction e.g. a p-n junction of a capacitor area, are covered by a material region that is impervious to such electrolyte. Suitable impervious materials include oxides, nitrides, carbides, low K polymers such as spin on organic polymeric dielectric materials, and metals. For such material compositions region thicknesses in the range 0.01 μm to 5 μm are typically employed. Thicknesses less than 0.01 μm tend to lead to discontinuities in the material region while thicknesses greater than 5 μm, although not precluded, are generally not needed. Generally to produce this cover for appropriate copper regions the copper pattern should be designed so that such cover is feasible.

In another embodiment unacceptable corrosion is prevented by designing the metal stack such that features connected to p-n junction arrays do not develop a net charge with respect to surrounding features. The corrosion is essentially eliminated if the appropriate electrochemical potential is not maintained on the metal feature with respect to its surroundings. Charge accumulation on the metal feature connected to a p-n junction is avoided by electrical connection to a charge dissipating circuit feature. Thus the circuit design, in one approach, avoids having a metal feature connected to only one side of the p-n junction.

Despite precautions, it is possible that due to, for example, processing irregularities photovoltaic corrosion occurs. For this reason, it is advantageous to monitor the possibility of a photovoltaic induced copper corrosion. Accordingly, in one embodiment, a test structure is processed together with a plurality of integrated circuits being manufactured. The test structure has a configuration including a capacitor or capacitor array or more generally p-n junction(s) that are optically accessible. The p-side of such junction are connected starting at the first metallization layer and connects to subsequent metallization through suitable vias. Thus the potential corrosion effect is limited to a small area of metallization. After processing 1) all copper regions that are electrically connected to a p-n junction, and 2) the material layer above such copper regions, the test structure is examined for unacceptable corrosion by techniques such as electrical testing, optical microscopy, scanning electron microscopy, focused ion beam spectroscopy, and/or transmission electron microscopy. If the test structure shows unacceptable corrosion then either the integrated circuits being processed are discarded or they are further processed to correct corrosion. By detecting unacceptable corrosion and eliminating or correcting devices with such corrosion, it is possible to avoid the unnecessary expense associated with processing to completion device entities that due to corrosion are not viable. Indeed such monitoring of light induced electrochemical corrosion offers advantages even for technology nodes less strict than 32 nm.

The following example is illustrative of concepts associated with the invention.

### EXAMPLE

An integrated circuit having dimensions consistent with the 65 nanometer technology node and having eight levels of interconnect metallization was employed. The upper level metals were removed by standard mechanical polishing using an Allied 0.05 μm colloidal silica suspension slurry on an Allied Multi-prep polisher. Polishing was continued for a suitable amount of time to deprocess down to and partially into the second level metal layer of the metallization stack. This metallization layer had features that electrically connected the copper runner to the boron-doped p-type bottom plate of a MOS capacitor array having a junction area of approximately 760 square micrometers. The sample was held with a plastic tweezers and placed under a stream of flowing deionized water. Light from a fiber microscope light source of approximately 10,000 lux was then placed approximately 1 cm from the sample and made incident on the capacitor array connected to the second layer metal regions for an extended period of time.

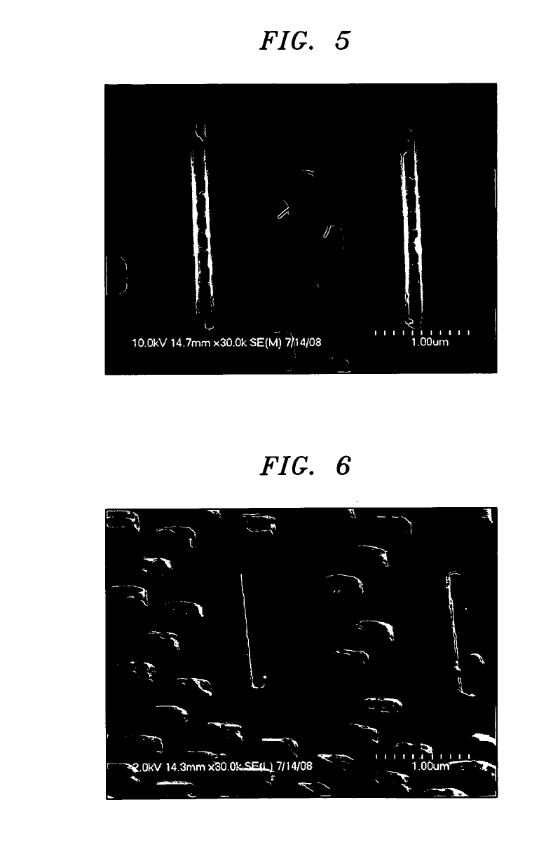

The effect of this treatment was investigated by electron microscopy using a Hitachi S4700 field emission SEM. The sample was inserted into the electron microscope and a 30 kV accelerating voltage was used. Images were taken both top down (FIG. 5) and at a 60 degree tilt angle (FIG. 6). These images showed dissolution of the runners electrically connected to the capacitor array. There were fifty-four of these connected second metal layer runners that were exposed to the light and water and each measured approximately 2.45 μm long×0.1 μm wide×0.26 μm thick. This dissolution continued into the copper vias below the second metal layer runners, i.e. the vias connecting the metal one layer to the metal two layer. These vias measured 0.1 μm in diameter and 0.15 μm thick. Dissolution ceased when all copper was dissolved leaving the tantalum barrier layer lining the vias and runners exposed.

1. A process of making an integrated circuit, said integrated circuit comprising a multiplicity of transistors, a integrated circuit element including a p-n junction, and a metallization stack including a multiplicity of patterned copper regions wherein said integrated circuit element is electrically connected to said metallization stack and electrically interacts with said transistors, said process comprising the steps of A) forming said plurality of transistors, B) forming said integrated circuit element and C) forming said metallization stack using at some time during said forming of said metallization stack an electrolyte whereby said metallization stack electrically interacts with 1) said p-n junction and 2) said multiplicity of transistors wherein said integrated circuit is at a technology node at least as small as 32 nm and during said forming of said metallization stack an expedient is used that limits the light induced electrochemical corrosion of said copper regions whereby unacceptable device characteristics are avoided.

2. The process of claim 1 wherein said expedient comprises substantially preventing light from impacting said junction.

3. The process of claim 2 wherein said junction is overlaid by an opaque material.

4. The process of claim 1 wherein said expedient comprises employing a charge dissipating structure such that charge accumulation on said copper interfacing with said electrolyte is substantially prevented.

5. The process of claim 1 wherein said expedient comprises preventing direct contact of said electrolyte with a portion of said copper region electrically connected to said junction.

6. The process of claim 5 wherein said portion is covered with an overlying material in the presence of said electrolyte.

7. The process of claim 1 wherein said integrated circuit element comprises a capacitor.

8. The process of claim 1 wherein said electrolyte comprises deionized water.

9. The process of claim 1 including the step of using a test structure to monitor said corrosion.

10. The process of claim 9 wherein said integrated circuit is discarded if substantial corrosion is monitored.

11. The process of claim 1 wherein said electrolyte comprises a cleaning solution.

12. The process of claim 1 wherein said integrated circuit element comprises an interface between p-doped silicon and n-doped silicon.

13. The process of claim 1 wherein said integrated circuit element comprises a capacitor array.

14. The process of claim 1 wherein said integrated circuit element comprises a diode.

15. A process of making an integrated circuit, said integrated circuit comprising a multiplicity of transistors, a integrated circuit element including a p-n junction, and a metallization stack including a multiplicity of patterned copper regions wherein said integrated circuit element is electrically connected to said metallization stack and electrically interacts with said transistors, said process comprising the steps of A) forming said plurality of transistors, B) forming said integrated circuit element and C) forming said metallization stack using at some time during said forming of said metallization stack an electrolyte whereby said metallization stack electrically interacts with 1) said p-n junction and 2) said multiplicity of transistors wherein during said forming of said metallization stack an expedient is used that limits the light induced electrochemical corrosion of said copper regions whereby unacceptable device characteristics are avoided and wherein a test structure is employed to monitor light induced electrochemical corrosion.

16. The process of claim 15 wherein said integrated circuit is discarded if substantial corrosion is monitored.
